(19) United States
(12) Patent Application Publication
(10) Pub. No.: US 2024/0410416 A1
(43) Pub. Date: Dec. 12, 2024

(54) FOLDABLE ROTATION SHAFT, DISPLAY DEVICE, AND BENDING TEST FIXTURE

(71) Applicant: BOE Technology Group Co., Ltd., Beijing (CN)

(72) Inventors: Yonghong ZHOU, Beijing (CN); Linlin XU, Beijing (CN); Shangchieh CHU, Beijing (CN); Xinyu WANG, Beijing (CN); Chong ZHANG, Beijing (CN)

(21) Appl. No.: 18/272,573

(22) PCT Filed: Jul. 6, 2022
(86) PCT No.: PCT/CN2022/104165

§ 371 Date: Jul. 15, 2023

(51) Int. Cl. F16C 11/04; H05K 5/02

(52) U.S. Cl. CPC F16C 11/04; H05K 5/0226

(57) ABSTRACT

Provided is a foldable rotation shaft, including: a base, a first support mechanism, and a second support mechanism. In an unfolded state, the base, the first support mechanism, and the second support mechanism are respectively configured to support a bending portion, a first portion, and a second portion of the flexible display panel. The second support mechanism is configured to cause, in a folded state, a region, proximal to the base, of the second portion to be bent into a curved shape along a direction going away from the first support mechanism. The first support mechanism is configured to cause, in the folded state, a curvature of a partial region of the first portion to be different from a curvature of the region, bent into the curved shape, of the second portion. The partial region is opposite to the region, bent into the curved shape, of the second portion.

### CROSS-REFERENCE TO RELATED APPLICATION

The present disclosure is a U.S. national stage of international application No. PCT/CN2022/104165, filed on Jul. 6, 2022, the content of which is herein incorporated by reference in its entirety.

### TECHNICAL FIELD

The present disclosure relates to the field of display devices, and in particular, relates to a foldable rotation shaft, a display device, and a bending test fixture.

### BACKGROUND

With the development of display technology, display devices are more and more widely used and are dispensable in people's daily work and life. Foldable display devices are gradually popular among people because of their small volume and good portability.

### SUMMARY

Embodiments of the present disclosure provide a foldable rotation shaft, a display device, and a bending test fixture. The technical solutions are as follows.

Some embodiments of the present disclosure provide a foldable rotation shaft. The foldable rotation shaft includes a base, a first support mechanism, and a second support mechanism; wherein the first support mechanism and the second support mechanism are rotatably connected to the base and are unfoldable and foldable relative to each other;
in an unfolded state, the base is configured to support a bending portion of a flexible display panel, the first support mechanism is configured to support a first portion, on one side of the bending portion, of the flexible display panel, and the second support mechanism is configured to support a second portion, on the other side of the bending portion, of the flexible display panel;
the second support mechanism is configured to cause, in a folded state, a region, proximal to the base, of the second portion to be bent into a curved shape along a direction going away from the first support mechanism; and
the first support mechanism is configured to cause, in the folded state, a curvature of a partial region of the first portion to be different from a curvature of the region, bent into the curved shape, of the second portion, wherein the partial region is opposite to the region, bent into the curved shape, of the second portion.

In some embodiments, in the folded state, the partial region is flat plate-shaped.

In some embodiments, the first support mechanism includes a first support plate and a connection arm, wherein one end of the connection arm is connected to a side of the first support plate, and the other end of the connection arm is rotatably connected to the base.

In some embodiments, the first support mechanism includes a first support plate and a first rotation assembly, wherein the first rotation assembly is disposed on a surface, distal from a support surface, of the first support plate, is connected to the first support plate, and is movably connected to the base, and the first rotation assembly is configured to drive the first support plate to rotate relative to the base and move relative to the base along a direction approaching or going away from the base.

In some embodiments, the first rotation assembly includes a first swing arm, a second swing arm, and a first middle frame connector; wherein
one end of the first swing arm is rotatably connected to the base, the other end of the first swing arm is slidably connected to the first middle frame connector, and the first middle frame connector is movable relative to the first swing arm along the direction approaching or going away from the base;
one end of the second swing arm is rotatably connected to the base, and the other end of the second swing arm is rotatably connected to the first middle frame connector; and
the first support plate is fixedly connected to the first middle frame connector.

In some embodiments, the second support mechanism includes a second support plate and a second rotation assembly, wherein the second rotation assembly is disposed on a surface, distal from a support surface, of the second support plate and is movably connected to the second support plate;
wherein the second rotation assembly is movably connected to the base and is configured to drive the second support plate to move relative to the base, and in the folded state, an included angle between the support surface of the second support plate and the support surface of the first support plate is an acute angle, an opening of the included angle facing toward the base.

In some embodiments, the second rotation assembly includes a third swing arm, a fourth swing arm, and a second middle frame connector; wherein
one end of the third swing arm is rotatably connected to the base, the other end of the third swing arm is slidably connected to the second middle frame connector, and the second middle frame connector is movable relative to the third swing arm along the direction approaching or going away from the base;
one end of the fourth swing arm is rotatably connected to the base, and the other end of the fourth swing arm is rotatably connected to the second middle frame connector; and
the second support plate is rotatably connected to the second middle frame connector and is rotatably connected to the third swing arm.

In some embodiments, the second support plate includes a plate body, a first connection portion, and a second connection portion, wherein the first connection portion and the second connection portion are disposed on a same surface of the plate body, are successively arranged along a direction approaching the base, and are disposed on a same side of the third swing arm and the second middle frame connector, wherein the first connection portion is rotatably connected to the second middle frame connector, and the second connection portion includes a drive groove; and
the third swing arm includes a first body portion and a connection rod, wherein two ends of the first body portion are respectively connected to the base and the second middle frame connector, and the connection rod is disposed between the base and the second middle frame connector, is disposed on a side, proximal to the second connection portion, of the first body portion, is partially within the drive groove, and is slidably connected to the second connection portion.

In some embodiments, a slot is disposed on a side, proximal to the base, of the second middle frame connector, wherein guiding chutes are disposed on two opposite side walls of the slot; and
guiding protrusions are disposed on two opposite sides of the first body portion, wherein the guiding protrusions are disposed on an end, distal from the base, of the first body portion, the end, distal from the base, of the first body portion is within the slot, and the guiding protrusions are within the guiding chutes.

In some embodiments, the second support mechanism is configured to cause, in the folded state, the region, proximal to the base, of the second portion to be bent into the curved shape along the direction going away from the first support mechanism; and
the first support mechanism is configured to cause, in the folded state, the partial region to be bent into a curved shape along a direction going away from the second support mechanism, and a curvature of the region, bent into the curved shape, of the first portion is greater than the curvature of the region, bent into the curved shape, of the second portion.

In some embodiments, the first support mechanism includes a first support plate and a first rotation assembly, wherein the first rotation assembly is disposed on a surface, distal from a support surface, of the first support plate, is movably connected to the first support plate, and is movably connected to the base, and the first rotation assembly is configured to drive the first support plate to rotate relative to the base and move relative to the base along a direction approaching or going away from the base;
the second support mechanism includes a second support plate and a second rotation assembly, wherein the second rotation assembly is disposed on a surface, distal from the support surface, of the second support plate, is movably connected to the second support plate, and is movably connected to the base, and the second rotation assembly is configured to drive the second support plate to rotate relative to the base and move relative to the base along the direction approaching or going away from the base; and
in the folded state, an included angle between the support surface of the second support plate and the support surface of the first support plate is an acute angle, wherein an opening of the included angle faces toward the base, and a distance between the support surface of the second support plate and an edge of the base to the base is greater than a distance between the support surface of the first support plate and the edge of the base to the base.

Some embodiments of the present disclosure provide a display device. The display device includes a first middle frame, a second middle frame, a flexible display panel, and the foldable rotation shaft as described above;
wherein the first middle frame is connected to a first support mechanism of the foldable rotation shaft, the second middle frame is connected to a second support mechanism of the foldable rotation shaft, and the flexible display panel includes a bending portion, and a first portion and a second portion that are disposed on two opposite sides of the bending portion, wherein the first portion is connected to the first middle frame, and the second portion is connected to the second middle frame.

In some embodiments, a thickness of the first middle frame is less than a thickness of the second middle frame.

Some embodiments of the present disclosure provide a bending test fixture of a flexible display panel. The bending test fixture includes: a first fixture and a second fixture that are unfoldable and foldable relative to each other; wherein
the first fixture includes a first support surface that is planar; and
the second fixture includes a second support surface, wherein the second support surface includes a first planar region, an inclined region, and a second planar region, wherein the first planar region and the second planar region are not coplanar, and the inclined region is disposed between the first planar region and the second planar region and is connected to the first planar region and the second planar region;
wherein the first support surface and the second support surface are configured to be respectively connected to a first portion and a second portion that are disposed on two sides of a bending portion of a flexible display panel, and the second planar region is proximal to the bending portion; and
the bending test fixture is configured to cause, in a folded state, a region, within the inclined region and the second planar region, of the second portion to be bent into a curved shape toward a direction going away from the first fixture, wherein a curvature of a partial region of the first portion is different from a curvature of the region, bent into the curved shape, of the second portion, and the partial region is opposite to the region, bent into the curved shape, of the second portion.

In some embodiments, in the folded state, the partial region is flat plate-shaped; or
in the folded state, the partial region is bent into a curved shape along a direction going away from the second fixture, and a curvature of the region, bent into the curved shape, of the first portion is greater than the curvature of the region, bent into the curved shape, of the second portion.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of a display device in the related art;

FIG. 2 is a bending schematic diagram of a display device according to some embodiments of the present disclosure;

FIG. 3 is a bending schematic diagram of a display device according to some embodiments of the present disclosure;

FIG. 4 is a schematic structural diagram of a foldable middle frame according to some embodiments of the present disclosure;

FIG. 5 is a schematic structural diagram of a foldable rotation shaft according to some embodiments of the present disclosure;

FIG. 6 is a schematic structural diagram of a flexible display panel according to some embodiments of the present disclosure;

FIG. 7 is a schematic structural diagram of a foldable rotation shaft according to some embodiments of the present disclosure;

FIG. 8 is a schematic diagram of breakdown structures of a foldable rotation shaft according to some embodiments of the present disclosure;

FIG. 9 is a schematic structural diagram of a foldable rotation shaft according to some embodiments of the present disclosure;

FIG. 10 is a schematic structural diagram of a first support mechanism according to some embodiments of the present disclosure;

FIG. 11 is a schematic structural diagram of a second support mechanism according to some embodiments of the present disclosure;

FIG. 12 is a schematic diagram of a partial structure of a base according to some embodiments of the present disclosure;

FIG. 13 is a schematic structural diagram of a foldable rotation shaft according to some embodiments of the present disclosure;

FIG. 14 is a schematic structural diagram of another foldable rotation shaft according to some embodiments of the present disclosure;

FIG. 15 is a schematic structural diagram of a foldable rotation shaft according to some embodiments of the present disclosure;

FIG. 16 is a schematic structural diagram of a display device according to some embodiments of the present disclosure;

FIG. 17 is a schematic structural diagram of a display device according to some embodiments of the present disclosure;

FIG. 18 is a schematic structural diagram of a bending test fixture of a flexible display panel according to some embodiments of the present disclosure; and

FIG. 19 is a schematic structural diagram of a flexible display panel according to some embodiments of the present disclosure.

### DETAILED DESCRIPTION

The present disclosure is described in further detail with reference to the accompanying drawings, to clearly present the objects, technical solutions, and advantages of the present disclosure.

It should be noted that unless otherwise defined, technical or scientific terms used in the embodiments of the present disclosure shall have ordinary meanings understandable by persons of ordinary skill in the art to which the disclosure belongs. The terms “first,” “second,” and the like used in the embodiments of the present disclosure are not intended to indicate any order, quantity or importance, but are merely used to distinguish the different components. The terms “comprise,” “include,” and derivatives or variations thereof are used to indicate that the element or object preceding the terms covers the element or object following the terms and its equivalents, and shall not be understood as excluding other elements or objects. The terms “connect,” “contact,” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly.

The foldable display device typically includes a foldable rotation shaft and a flexible display panel. The foldable rotation shaft can be folded relatively, and the flexible display panel is disposed on a side of the foldable rotation shaft. In the case that the foldable rotation shaft is unfolded, the flexible display panel is flattened on the foldable rotation shaft. In the case that the foldable rotation shaft is folded, the flexible display panel is folded between two portions of the foldable rotation shaft that are relatively folded.

To avoid damage to the flexible display panel during being bent, the foldable rotation shaft is designed to form, in the folded state, a space on a support mechanism to accommodate a bending region of the flexible display panel, such that the flexible display panel is bent into a teardrop shape.

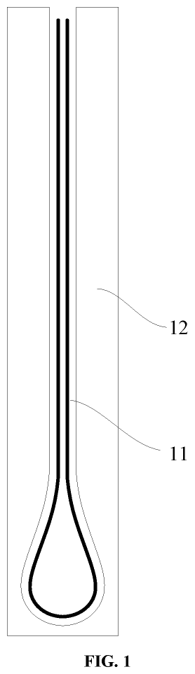

FIG. 1 is a schematic structural diagram of a display device in the related art. As illustrated in FIG. 1, the display device includes a flexible display panel 11 and a foldable middle frame 12. The flexible display panel 11 includes front and back sides that are opposite to each other. The front side is a display surface for display. The foldable middle frame 12 is disposed on the back side of the flexible display panel 11 and is connected to the flexible display panel 11. In the case that the foldable middle frame 12 is unfolded, the flexible display panel 11 is flattened. In the case that the foldable middle frame 12 is folded, regions, on both sides of a bending portion of the flexible display panel 11, of the foldable middle frame 12 are recessed inward, such that the flexible display panel 11 is symmetrical teardrop-shaped.

Because the flexible display panel 11 is symmetrical teardrop-shaped, the regions, on both sides of the bending portion of the flexible display panel 11, of the foldable middle frame 12 are recessed inward to the same extent. In this way, spaces for accommodating other structures inside two portions that are unfoldable and foldable relative to each other of the foldable middle frame 12 have the same shape. However, inside the display device, the structures arranged inside the two portions are not exactly the same. For example, a battery is usually arranged inside one of the two portions, and a speaker and a microphone are usually arranged inside the other of the portions, which is not conducive to the utilization of space inside the display device and the arrangement of the internal structures of the display device.

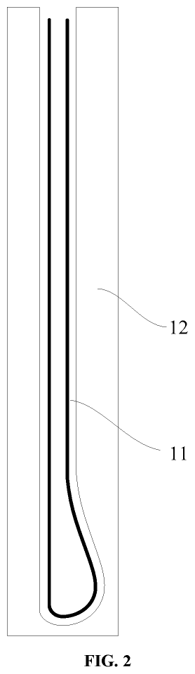

FIG. 2 is a bending schematic diagram of a display device according to some embodiments of the present disclosure. The display device may be, but is not limited to, a smartphone, a laptop computer, or a tablet computer. As illustrated in FIG. 2, the display device includes a flexible display panel 11 and a foldable middle frame 12. In the case that the display device is folded, a region, on a side of a bending portion of the flexible display panel 12, of the foldable middle frame 11 is recessed inward into a curved shape. That is, a curvature is greater than 0. A region disposed on the other side is not recessed inward and remains flat. That is, a curvature is 0. The flexible display panel 11 is still bent into a teardrop shape, but the teardrop shape is asymmetrical. The recess is only formed on one of the two sides of the foldable middle frame 12. Therefore, internal spaces of two portions that are foldable relative to each other of the display device have different shapes, which facilitates an arrangement of internal structures of the display device according to the shape of the internal space, and thus the internal structures of the display device are more compact. In addition, a thickness of the side, which is not recessed inward, of the foldable middle frame 12 is arranged to be thinner, and thus a thickness of the display device in the folded state is reduced.

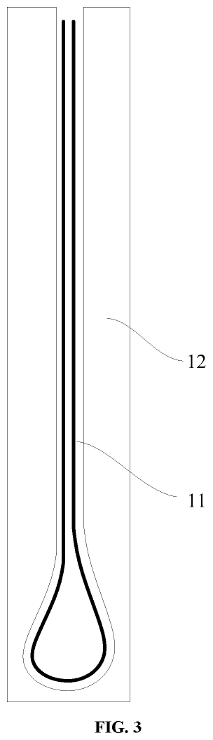

FIG. 3 is a bending schematic diagram of a display device according to some embodiments of the present disclosure. As illustrated in FIG. 3, in the case that the display device is folded, the region, on one side of the bending portion of the flexible display panel 11, of the foldable middle frame 12 is recessed inward, and the region disposed on the other side is also recessed inward. But the two sides are recessed inward with different degrees, that is, have different curvatures. The flexible display panel 11 is also bent into a teardrop shape which is asymmetrical. In this way, the internal spaces of the two relatively foldable portions of the display device also have different shapes, which facilitates the arrangement of the internal structures of the display device according to the shape of the internal space, and thus the internal structures of the display device are more compact.

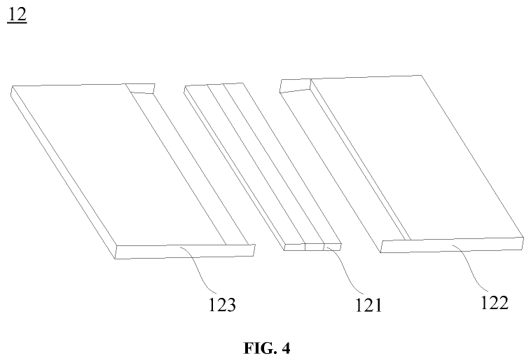

FIG. 4 is a schematic structural diagram of a foldable middle frame according to some embodiments of the present disclosure. As illustrated in FIG. 4, the foldable middle frame 12 includes a foldable rotation shaft 121, a first middle frame 122, and a second middle frame 123. The first middle frame 122 and the second middle frame 123 are connected to the foldable rotation shaft 121.

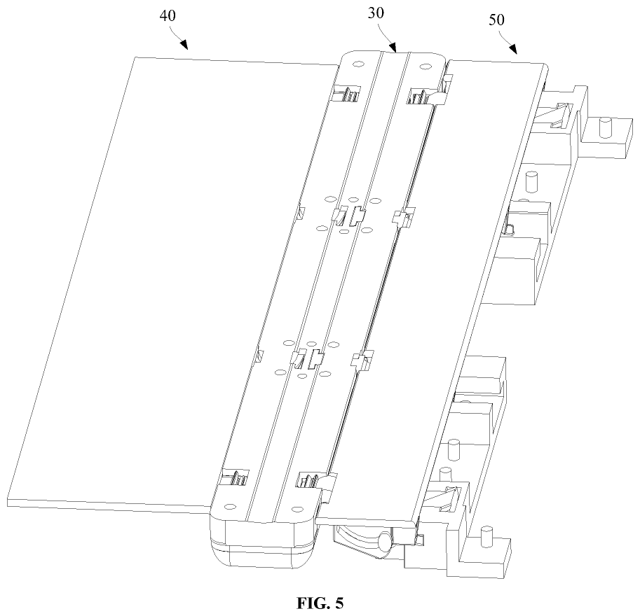

FIG. 5 is a schematic structural diagram of a foldable rotation shaft according to some embodiments of the present disclosure. As illustrated in FIG. 5, the foldable rotation shaft1 21 includes a base 30, a first support mechanism 40, and a second support mechanism 50. The first support mechanism 40 and the second support mechanism 50 are rotatably connected to the base 30 and are unfoldable and foldable relative to each other.

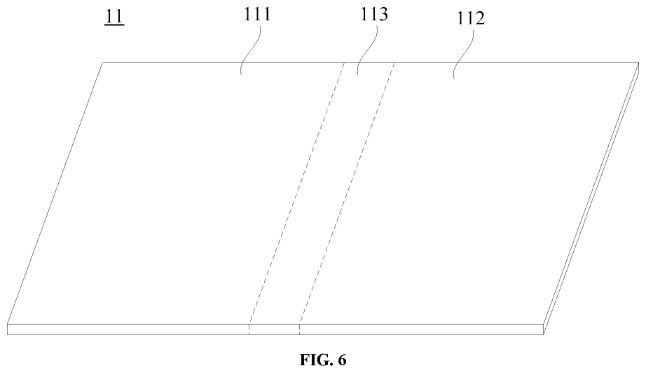

FIG. 6 is a schematic structural diagram of a flexible display panel according to some embodiments of the present disclosure. As illustrated in FIG. 6, the flexible display panel 11 includes a front side and a back side that are opposite to each other, wherein the front side is a display surface for display. In the display device, the foldable rotation shaft 121 is arranged on the back side of the flexible display panel 11. The flexible display panel 11 includes a bending portion 113, a first portion 111, and a second portion 112. The bending portion 113 is disposed between the first portion 111 and the second portion 112, and is connected to the first portion 111 and the second portion 112. During a process of being bent, a bending deformation of the flexible display panel is mainly generated in the bending portion 113, but it does not mean that the first portion 111 and the second portion 112 necessarily do not generate the deformation. The foldable rotation shaft 121 has an unfolded state and a folded state. In the unfolded state, the flexible display panel 11 is flattened. In the folded state, the flexible display panel 11 is in a bending state. That is, in combination with FIG. 2 and FIG. 3, the second support mechanism 50 is configured to cause, in the folded state, a region, proximal to the base 30, of the second portion 112 to be bent into a curved shape along a direction going away from the first support mechanism 40. The first support mechanism 40 is configured to cause, in the folded state, a curvature of a partial region of the first portion 111 to be different from a curvature of the region, bent into the curved shape, of the second portion 112. The partial portion of the first portion 111 is opposite to the region, bent into the curved shape, of the second portion 112.

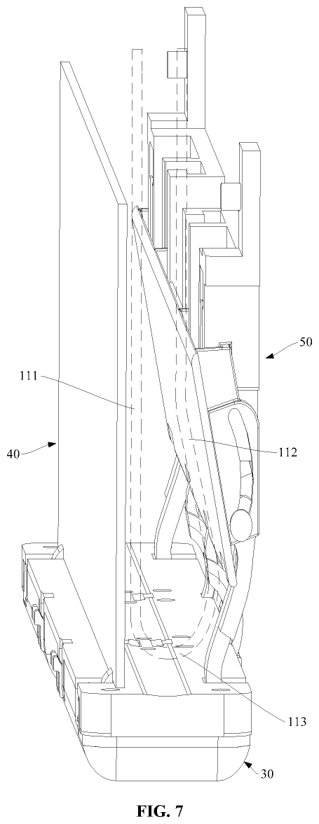

In some embodiments, the unfolded state is shown in FIG. 5, and the folded state is shown in FIG. 7.

In the unfolded state, the base 30 is configured to support the bending portion 113 of the flexible display panel, the first support mechanism 40 is configured to support the first portion 111, on one side of the bending portion 113, of the flexible display panel, and the second support mechanism 50 is configured to support the second portion 112, on the other side of the bending portion 113, of the flexible display panel.

Referring to FIG. 7, the second support mechanism 50 is configured to cause, in the folded state, the region, proximal to the base 30, of the second portion 112 of the flexible display panel 11 to be bent into the curved shape along the direction going away from the first support mechanism 40. The first support mechanism 40 is configured to cause, in the folded state, the partial region of the first portion 111 to be flat plate-shaped. The partial region of the first portion 111 is opposite to the region, bent into the curved shape, of the second portion 112.

By providing the foldable rotation shaft 121 with the base 30, and the first support mechanism 40 and the second support mechanism 50 that are unfoldable and foldable relative to each other, in the unfolded state, the base 30, the first support mechanism 40, and the second support mechanism 50 respectively support the bending portion 113, the first portion 111, and the second portion 112 of the flexible display panel 11, such that the flexible display panel 11 remains in the unfolded state. In the folded state, the second support mechanism 50 causes the region, proximal to the base 30, of the second portion 112 of the flexible display panel 11 to be bent into the curved shape along the direction going away from the first support mechanism 40, and the first support mechanism 40 causes the partial region of the first portion 111 to be flat, such that the flexible display panel 11 is bent into an asymmetric teardrop shape. Because the first portion 111 remains flat and the second portion 112 is bent into the asymmetrical teardrop shape, the first support mechanism 40 does not need to be recessed inward in the folded state. In this way, in two foldable portions of the display device applying this rotation shaft 121, the thickness of the portion where the first support mechanism 40 is disposed is arranged to be thinner, which is conducive to reducing the thickness of the display device in the folded state.

For some display devices, due to the different structures of two relatively foldable portions, the thicknesses of the two portions are generally designed to be different. Using a laptop computer in regular use as an example, in two portions that are foldable relative to each other, a thickness of one portion placed on a table and with internal structures such as circuit boards, hard disks, and batteries arranged therein is usually large, while a thickness of another portion with fewer internal structures arranged therein is usually small. By applying the foldable rotation shaft of the present disclosure to the laptop computer, the second support mechanism 50 is arranged within the portion placed on the table, and the first support mechanism 40 is arranged within the other portion, which fits the thickness of the two portions of the laptop computer well.

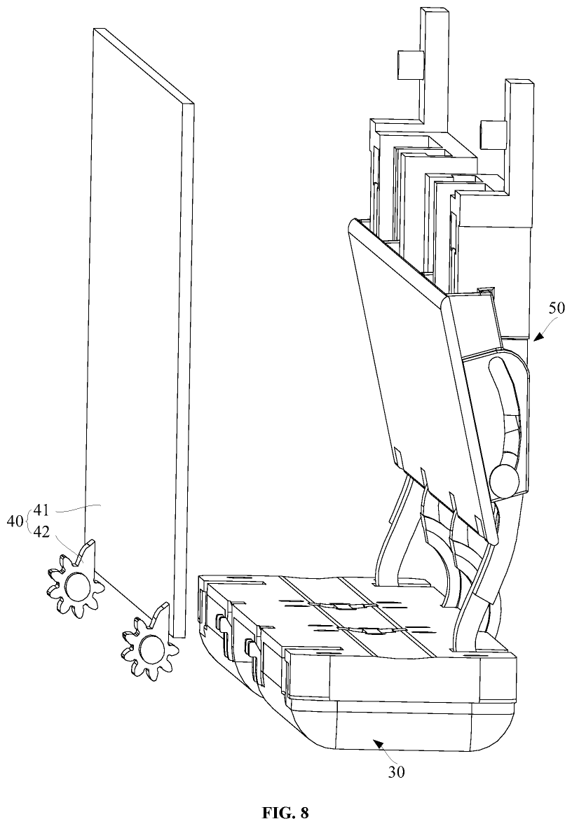

FIG. 8 is a schematic diagram of breakdown structures of a foldable rotation shaft according to some embodiments of the present disclosure. As illustrated in FIG. 8, the first support mechanism 40 includes a first support plate 41 and a connection arm 42. One end of the connection arm 42 is connected to one side of the first support plate 41, and the other end of the connection arm 42 is rotatably connected to the base 30.

The first support plate 41 is hinged to the base 30 by the connection arm 42, such that the first support plate 41 is capable of rotating relative to the base 30. A surface of the first support plate 41 opposite to the second support mechanism 50 in the folded state is a support surface of the first support plate 41, and the support surface of the first support plate 41 is configured to support the first portion 111 of the flexible display panel 11. The first portion 111 of the flexible display panel 11 is supported by the support surface of the first support plate 41, such that the first portion 111 of the flexible display panel 11 remains flat in both the unfolded state and the folded state.

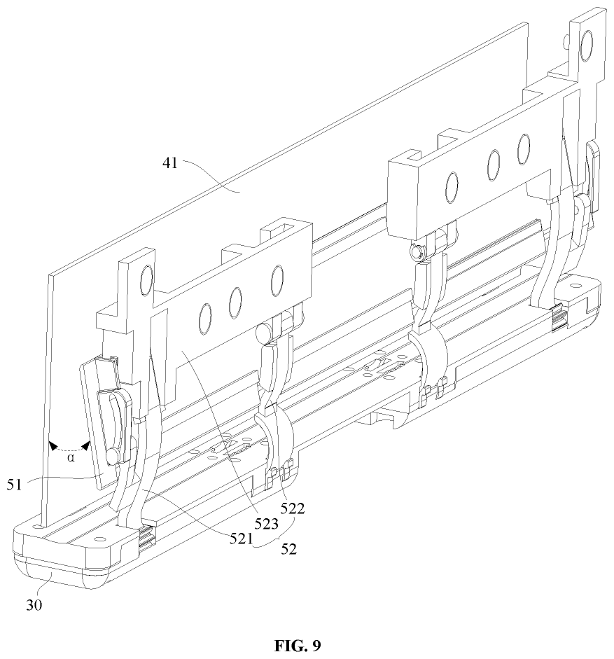

FIG. 9 is a schematic structural diagram of a foldable rotation shaft according to some embodiments of the present disclosure. As illustrated in FIG. 9, the second support mechanism 50 includes a second support plate 51 and a second rotation assembly 52. The second rotation assembly 52 is disposed on a surface, distal from a support surface, of the second support plate 51. The second rotation assembly 52 is movably connected to the second support plate 51. The second rotation assembly 52 is movably connected to the base 30.

The second rotation assembly 52 is configured to drive the second support plate 51 to move relative to the base 30. In the folded state, an included angle α between the support surface of the second support plate 51 and the support surface of the first support plate 41 is acute, and an opening of the included angle α faces toward the base 30.

A surface of the second support plate 51 opposite to the first support mechanism 40 in the folded state is the support surface of the second support plate 51. The support surface of the second support plate 51 is configured to support the second portion 112 of the flexible display panel 11. During a process that the first support mechanism 40 and the second support mechanism 50 are unfoldable and foldable relative to each other, the second rotation assembly 52 drives the second support plate 51 to move relative to the base 30, and a state of the second support plate 51 is changed under the action of the second rotation assembly 52. In the folded state, the second rotation assembly 52 drives the second support plate 51 to be inclined relative to the first support plate 41. The included angle between the support surface of the second support plate 51 and the support surface of the first support plate 41 is acute, and the opening of the included angle faces toward the base 30. In this way, the region, proximal to the base 30, of the second portion 112 of the flexible display panel 11 has a space bent toward the direction going away from the first support mechanism 40, which forms a teardrop shape.

As illustrated in FIG. 9, the second rotation assembly 52 includes a third swing arm 521, a fourth swing arm 522, and a second middle frame connector 523.

One end of the third swing arm 521 is rotatably connected to the base 30, and the other end of the third swing arm 521 is slidably connected to the second middle frame connector 523. The second middle frame connector 523 is movable relative to the third swing arm 521 along the direction approaching or going away from the base 30. One end of the fourth swing arm 522 is rotatably connected to the base 30, and the other end of the fourth swing arm 522 is rotatably connected to the second middle frame connector 523. The second support plate 51 is rotatably connected to the second middle frame connector 523 and is rotatably connected to the third swing arm 521.

During a process that the first support mechanism 40 and the second support mechanism 50 are unfoldable and foldable relative to each other, the third swing arm 521 and the fourth swing arm 522 both rotate relative to the base 30. During this process, the second middle frame connector 523 rotates relative to the base 30 and also moves relative to the third swing arm 521 along the direction approaching or going away from the base 30. The second support plate 51 is connected to both the second middle frame connector 523 and the third swing arm 521, and the movement of the second support plate 51 is influenced by both the second middle frame connector 523 and the third swing arm 521. The second support plate 51 is inclined relative to the first support plate 41 in the folded state under the action of the second middle frame connector 523 and the third swing arm 521.

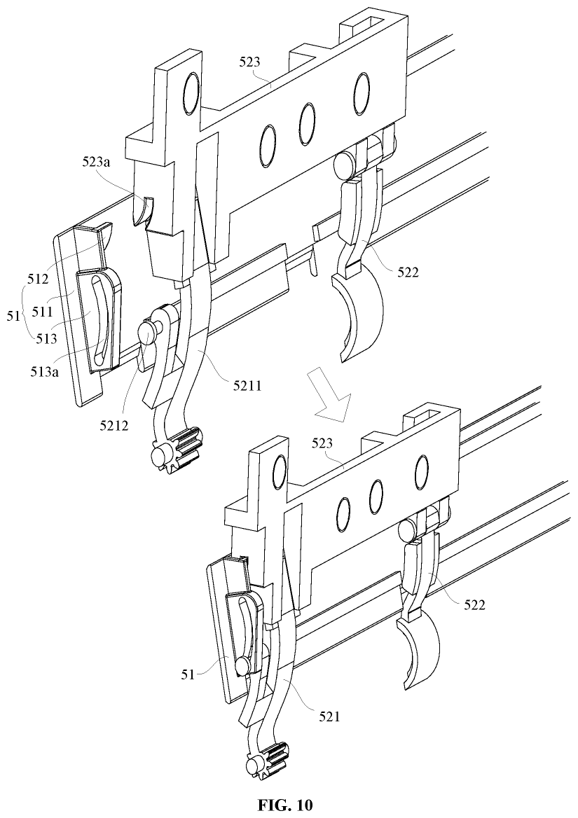

FIG. 10 is a schematic structural diagram of a first support mechanism according to some embodiments of the present disclosure. As illustrated in FIG. 10, the second support plate 51 includes a plate body 511, a first connection portion 512, and a second connection portion 513. The first connection portion 512 and the second connection portion 513 are disposed on the same surface of the plate body 511 and are successively arranged along a direction approaching the base 30. That is, the second connection portion 513 is closer to the base 30 than the first connection portion 512.

The first connection portion 512 and the second connection portion 513 are disposed on the same side of the third swing arm 521 and the second middle frame connector 523. The first connection portion 512 is rotatably connected to the second middle frame connector 523. The second connection portion 513 includes a drive groove.

The third swing arm 521 includes a first body portion 5211 and a connection rod 5212. Two ends of the first body portion 5211 are respectively connected to the base 30 and the second middle frame connector 523. The connection rod 5212 is disposed between the base 30 and the second middle frame connector 523, and the connection rod 5212 is disposed on a side, proximal to the second connection portion 513, of the first body portion 5211. The connection rod 5212 is partially within the drive groove 513a and is slidably connected to the second connection portion 513.

The plate body 511 of the second support plate 51 is configured to support the region, proximal to the base 30, of the second portion 112 of the flexible display panel 11. The first connection portion 512 is rotatably connected to the second middle frame connector 523. The drive groove 513a of the second connection portion 513 forms a cooperation with the connection rod 5212. During a process that the second middle frame connector 523 moves relative to the third swing arm 521 along the direction approaching or going away from the base 30, the connection rod 5212 moves in the drive groove 513a, generating a pushing effect on side walls of the drive groove 513a, which drives the second support plate 51 to rotate relative to the second middle frame connector 523, and thus the included angle between the support surface of the second support plate 51 and the support surface of the first support plate 41 changes.

The drive groove 513a is curved or linear.

Exemplarily, the first connection portion 512 is a curved arm disposed on a side, distal from the base 30, of the plate body 511. One end of the curved arm is connected to the plate body 511, and the other end extends along the direction going away from the base 30. A surface, proximal to the first connection portion 512, of the second middle frame connector 523 has a curved groove 523a. The curved arm is within the curved groove 523a, and the curved arm is capable of sliding along the curved groove 523a, such that the second support plate 51 is capable of rotating about an axis of the curved arm or an axis of the curved groove 523a relative to the second middle frame connector 523. Because an axis of rotation of the second support plate 51 is the axis of the curved arm or the axis of the curved groove 523a, a position of the axis of rotation of the second support plate 51 is adjusted by adjusting radii of the curved arm and the curved groove 523a.

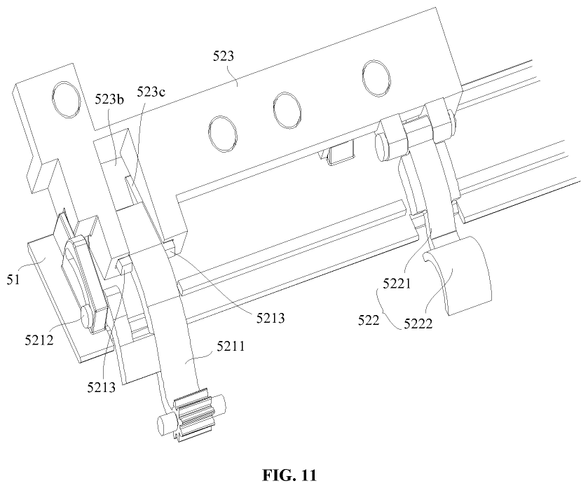

FIG. 11 is a schematic structural diagram of a second support mechanism according to some embodiments of the present disclosure. As illustrated in FIG. 11, a slot 523b is disposed on a side, proximal to the base 30, of the second middle frame connector 523, and guiding chutes 523c are disposed on two opposite side walls of the slot 523b.

Guiding protrusions 5213 are disposed on two opposite sides of the first body portion 5211, and the guiding protrusions 5213 are disposed on an end, distal from the base 30, of the first body portion 5211. The end, distal from the base 30, of the first body portion 5211 is within the slot 523b, and the guiding protrusions 5213 are within the guiding chutes 523c.

During a process that the second middle frame connector 523 moves along the direction approaching or going away from the base 30 relative to the third swing arm 521, the guiding protrusions 5213 slide in the guiding chutes 523c. The second middle frame connector 523 moves more smoothly by the cooperation formed between the guiding protrusions 5213 and the guiding chutes 523c.

As illustrated in FIG. 11, the fourth swing arm 522 includes a second body portion 5221 and a curved arm 5222. One end of the curved arm 5222 is connected to one end of the second body portion 5221. The other end of the second body portion 5221 is rotatably connected to the second middle frame connector 523. The curved arm 5222 is rotatably connected to the base 30.

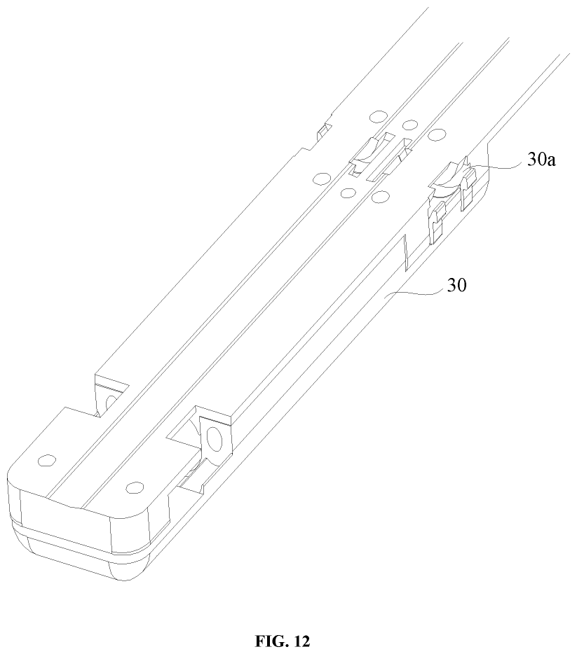

The fourth swing arm 522 is connected to the base 30 in a similar way as the second support plate 51 connected to the second middle frame connector 523. FIG. 12 is a schematic diagram of a partial structure of a base according to some embodiments of the present disclosure. As illustrated in FIG. 12, the base 30 includes a curved slot 30a. The curved arm 5222 is inserted into the curved slot 30a, and the curved arm 5222 slidably cooperates with the curved slot 30a. During the process that the first support mechanism 40 and the second support mechanism 50 are unfoldable and foldable relative to each other, the curved arm 5222 moves along the curved slot 30a, causing the fourth swing arm 522 to rotate about an axis of the curved arm 5222 or an axis of the curved slot 30a relative to the base 30. During the process that the first support mechanism 40 and the second support mechanism 50 are gradually folded, the curved arm 5222 gradually moves outward from the curved slot 30a, such that a distance between the second middle frame connector 523 and the base 30 gradually increases, and thus the second middle frame connector 523 moves along the direction going away from the base 30 relative to the third curved arm 5222.

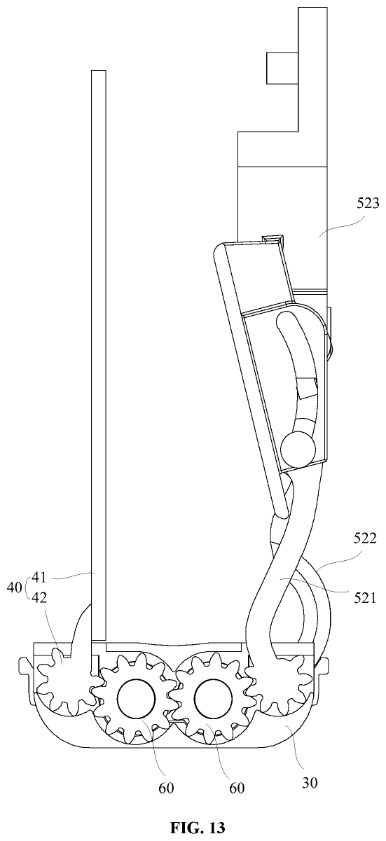

FIG. 13 is a schematic structural diagram of a foldable rotation shaft according to some embodiments of the present disclosure. The foldable rotation shaft also includes a synchronization gear 60 as illustrated in FIG. 13. An end, distal from the first support plate 41, of the connection arm 42 has a plurality of teeth, and an end, distal from the second middle frame connection portion 523, of the third swing arm 521 has a plurality of teeth. The teeth of the connection arm 42 and the teeth of the third swing arm 521 both engage the synchronization gear 60, such that movements of the first support mechanism 40 and the second support mechanism 50 are synchronized.

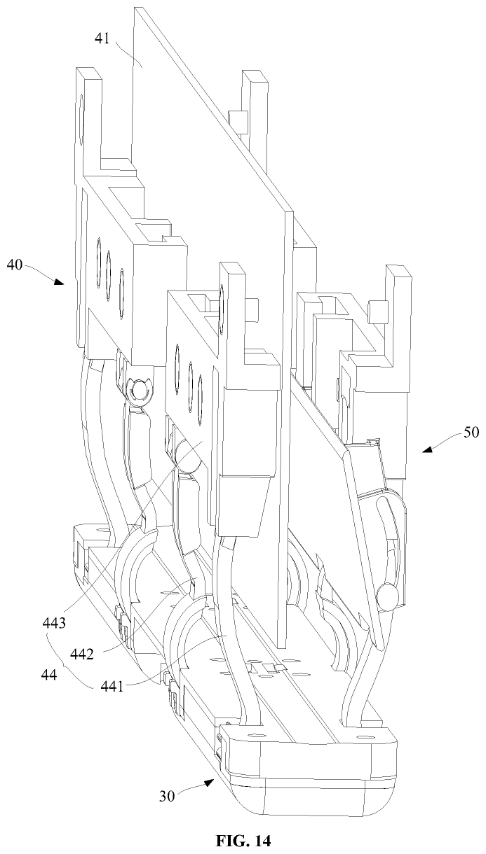

FIG. 14 is a schematic structural diagram of another foldable rotation shaft according to some embodiments of the present disclosure. A difference between the foldable rotation shaft and the foldable rotation shaft illustrated in FIG. 8 to FIG. 12 lies in the structure of the first support mechanism 40. As illustrated in FIG. 14, in the foldable rotation shaft, the first support mechanism 40 includes the first support plate 41 and a first rotation assembly 44. The first rotation assembly 44 is disposed on a surface, distal from the support surface, of the first support plate 41 and is connected to the first support plate 41. The first rotation assembly 44 is movably connected to the base 30, and is configured to drive the first support plate 41 to rotate relative to the base 30 and move relative to the base 30 along the direction approaching or going away from the base 30.

During the process of being folded, the first rotation assembly 44 drives the first support plate 41 to rotate while moving along the direction going away from the base 30, such that the first portion 111 of the flexible display panel 11 moves toward the direction going away from the base 30. In this way, the space formed between the first support mechanism 40, the second support mechanism 50, and the base 30 to accommodate the flexible display panel 11 in the folded state is increased, which avoids the bending portion 113 of the flexible display panel 11 and the base 30 from squeezing each other in the closed state, and thus a large stress is prevented from being generated between the bending portion 113 of the flexible display panel 11 and the base 30.

As illustrated in FIG. 14, the first rotation assembly 44 includes a first swing arm 441, a second swing arm 442, and a first middle frame connector 443.

One end of the first swing arm 441 is rotatably connected to the base 30, and the other end is slidably connected to the first middle frame connector 443. The first middle frame connector 443 is movable relative to the first swing arm 441 along the direction approaching or going away from the base 30. One end of the second swing arm 442 is rotatably connected to the base 30, and the other end is rotatably connected to the first middle frame connector 443. The first support plate 41 is fixedly connected to the first middle frame connector 443.

A difference between a structure of the first swing arm 441 and a structure of the third swing arm 521 lies in that the first swing arm 441 is not provided with the connection rod 5212. Apart from this, the structure of the first swing arm 441 is the same as the structure of the third swing arm 521. A structure of the second swing arm 442 is the same as a structure of the fourth swing arm 522. A difference between a structure of the first middle frame connector 443 and a structure of the second middle frame connector 523 lies in that the first middle frame connector 443 is not provided with the curved groove 523a. Apart from this, the structure of the first middle frame connector 443 is the same as the structure of the second middle frame connector 523.

During the process that the first support mechanism 40 and the second support mechanism 50 are unfoldable and foldable relative to each other, the first swing arm 441 and the second swing arm 442 rotate relative to the base 30, and the first middle frame connector 443 moves relative to the first swing arm 441 along the direction approaching or going away from the base 30 under the action of the first swing arm 441 and the second swing arm 442. Because the first support plate 41 is fixedly connected to the first middle frame connector 443, the first support plate 41 is movable along with the first middle frame connector 443 along the direction approaching or going away from the base 30. During the process that the foldable rotation shaft changes from the unfolded state to the folded state, a distance that the first support plate 41 moves along the direction approaching or going away from the base 30 is greater or less than a distance that the second support plate 51 moves along the direction approaching or going away from the base 30. In some embodiments, the distances are equal.

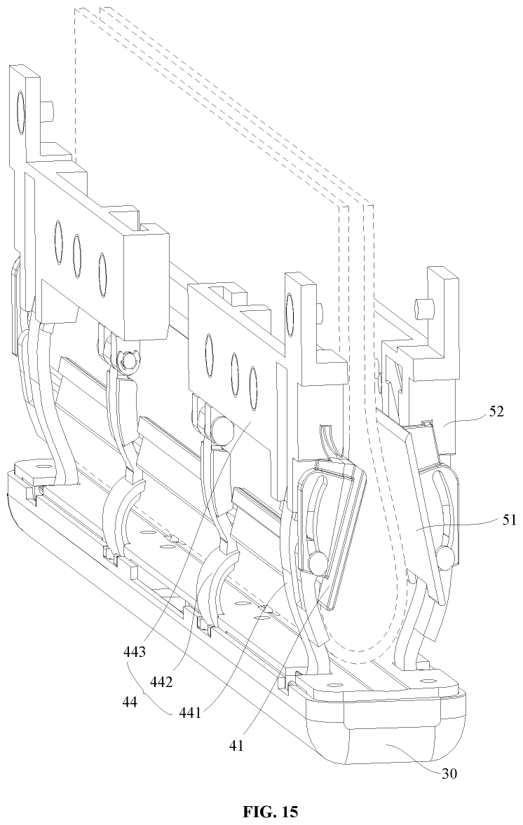

FIG. 15 is a schematic structural diagram of a foldable rotation shaft according to some embodiments of the present disclosure. As illustrated in FIG. 15, in some embodiments, in the unfolded state, the base 30 is configured to support the bending portion 113 of the flexible display panel, the first support mechanism 40 is configured to support the first portion 111, on one side of the bending portion 113, of the flexible display panel, and the second support mechanism 50 is configured to support the second portion 112, on the other side of the bending portion 113, of the flexible display panel.

The second support mechanism 50 is configured to cause, in the folded state, the region, proximal to the base 30, of the second portion 112 to be bent into a curved shape along the direction going away from the first support mechanism 40.

The first support mechanism 40 is configured to cause, in the folded state, a partial region of the first portion 111 to be bent into a curved shape along the direction going away from the second support mechanism 50. The partial region is opposite to the region, bent into the curved shape, of the second portion 112. A curvature of the region, bent into the curved shape, of the first portion 111 is greater than a curvature of the region, bent into the curved shape, of the second portion 112.

That is, the flexible display panel in the folded state illustrated in FIG. 15 is presented as illustrated in FIG. 3.

As illustrated in FIG. 15, the first support mechanism 40 includes the first support plate 41 and the first rotation assembly 44. The first rotation assembly 44 is disposed on the surface, distal from the support surface, of the first support plate 41. The first rotation assembly 44 is movably connected to the first support plate 41 and is movably connected to the base 30. The first rotation assembly 44 is configured to drive the first support plate 41 to rotate relative to the base 30 and move relative to the base 30 along the direction approaching or going away from the base 30.

The second support mechanism 50 includes the second support plate 51 and the second rotation assembly 52. The second rotation assembly 52 is disposed on the surface, distal from the support surface, of the second support plate 51. The second rotation assembly 52 is movably connected to the second support plate 51 and is movably connected to the base 30. The second rotation assembly 52 is configured to drive the second support plate 51 to rotate relative to the base 30 and move relative to the base 30 along the direction approaching or going away from the base 30.

In the folded state, the included angle between the support surface of the second support plate 51 and the support surface of the first support plate 41 is acute, and the opening of the included angle faces toward the base 30. A distance between the support surface of the second support plate 51 and an edge of the base 30 to the base 30 is greater than a distance between the support surface of the first support plate 41 and the edge of the base 30 to the base 30.

In some embodiments, a structure of the second rotation assembly 52 is the same as a structure of the second rotation assembly 52 illustrated in FIG. 9 or FIG. 10. A structure of the first rotation assembly 44 is similar to a structure of the first rotation assembly 44 illustrated in FIG. 14. The first support plate 41 is connected to the first rotation assembly 44 in the embodiments illustrated in FIG. 15 in the same way as the second support plate 51 connected to the second rotation assembly 52 illustrated in FIG. 10.

In the embodiments illustrated in FIG. 15, the structure of the first support mechanism 40 is similar to the structure of the second support mechanism 50, the difference only lies in different sizes. Therefore, during the process that the foldable rotation shaft changes from the unfolded state to the folded state, the distance that the second support plate 51 moves along the direction approaching or going away from the base 30 is greater than the distance that the first support plate 41 moves along the direction approaching or going away from the base 30, such that the distance between the support surface of the support plate 51 and the edge of the base 30 to the base 30 is greater than the distance between the support surface of the first support plate 41 and the edge of the base 30 to the base 30. The first support mechanism 40 and the second support mechanism 50 occupy different spaces due to different sizes, which facilitates a rational arrangement of the internal structures inside the two portions of the display device that are unfoldable and foldable relative to each other, and thus the internal structures of the display device are more compact. For example, in the case the space occupied by the first support mechanism 40 is smaller than the space occupied by the second support mechanism 50, a battery is provided within a portion, where the first support mechanism 40 is disposed, of the two portions that are unfoldable and foldable relative to each other of the display device, such that there is more space to arrange the battery.

In the folded state, the second support plate 51 causes the region, proximal to the base 30, of the second portion 112 of the flexible display panel 11 to be bent into a curved shape along the direction going away from the first support plate 41, and the first support plate 41 causes the region, proximal to the base 30, of the first portion 111 of the flexible display panel 1 Ito be bent into a curved shape along the direction going away from the second support plate 51. In this way, the flexible display panel 11 is bent into a teardrop shape. During the process from the unfolded state to the closed state, the distance that the second support plate 51 moves along the direction approaching or going away from the base 30 is different from the distance that the first support plate 41 moves along the direction approaching or going away from the base 30, and thus the flexible display panel 11 is bent into an asymmetric teardrop shape.

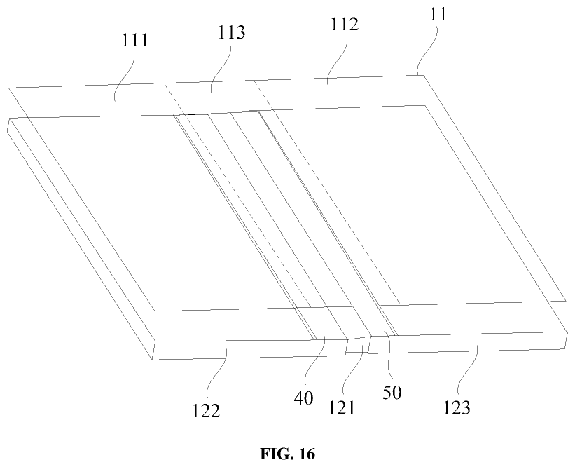

FIG. 16 is a schematic structural diagram of a display device according to some embodiments of the present disclosure. As illustrated in FIG. 16, the display device includes the first middle frame 122, the second middle frame 123, the flexible display panel 11, and the foldable rotation shaft 121 as described in any of FIG. 5 to FIG. 14. The flexible display panel 11 is separated in FIG. 16 for ease of display the structure.

The first middle frame 122 is connected to the first support mechanism 40 of the foldable rotation shaft 121, and the second middle frame 123 is connected to a second support mechanism 50 of the foldable rotation shaft 121. The first portion 111 of the flexible display panel 11 is connected to the first middle frame 122, and the second portion 112 of the flexible display panel 11 is connected to the second middle frame 123.

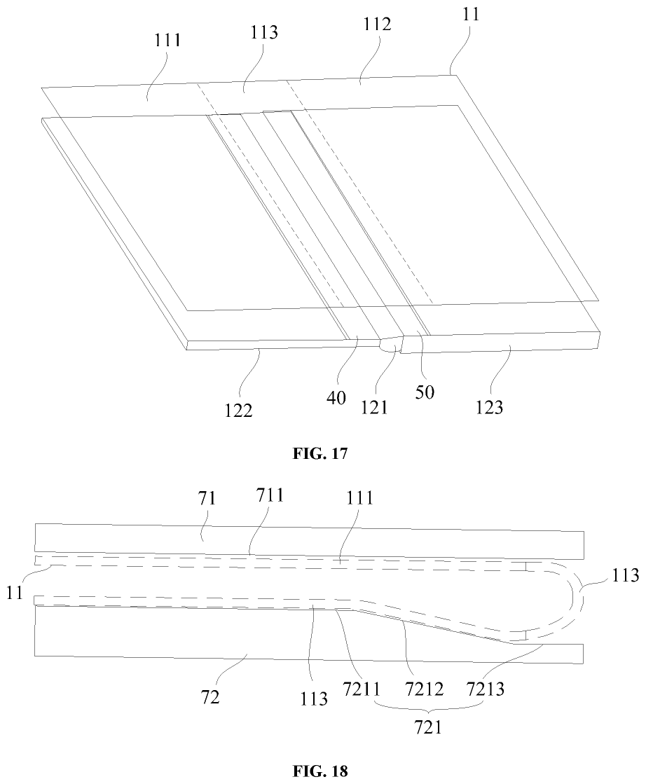

FIG. 17 is a schematic structural diagram of a display device according to some embodiments of the present disclosure. As illustrated in FIG. 17, in this display device, a thickness of the first middle frame 122 is less than a thickness of the second middle frame 123. In the foldable middle frame 12, the first middle frame 122 is connected to the first support mechanism 40 of the foldable rotation shaft 121, and the second middle frame 123 is connected to the second support mechanism 50 of the foldable rotation shaft 121. Only a side where the second support mechanism 50 is disposed is recessed, such that the flexible display panel 11 is bent into a teardrop shape, and a side where the first support mechanism 40 is disposed is not recessed. Therefore, in the first middle frame 122 and the second middle frame 123 that are foldable relative to each other of the display device, the thickness of the first middle frame 122 is arranged to be thinner, which reduces the thickness of the display device in the folded state.

In other embodiments, the foldable rotation shaft 121 of the display device is the foldable rotation shaft as illustrated in FIG. 15, such that the flexible display panel is asymmetrically teardrop-shaped as illustrated in FIG. 3 when folded.

FIG. 18 is a schematic structural diagram of a bending test fixture of a flexible display panel according to some embodiments of the present disclosure. As illustrated in FIG. 18, the bending test fixture includes a first fixture 71 and a second fixture 72 that are unfoldable and foldable relative to each other.

The first fixture 71 has a first support surface 711 that is planar.

The second fixture 72 has a second support surface 721. The second support surface 721 includes a first planar region 7211, an inclined region 7212, and a second planar region 7213. The first planar region 7211 and the second planar region 7213 are not coplanar, and the inclined region 7212 is disposed between the first planar region 7211 and the second planar region 7213, and is connected to the first planar region 7211 and the second planar region 7213. The first support surface 711 and the second support surface 721 are configured to be respectively connected to the first portion 111 and the second portion 112 of the flexible display panel 11, and the second planar region 7213 is proximal to the bending portion 113 of the flexible display panel 11.

The bending test fixture is configured to cause, in the folded state, a region, within the inclined region 7212 and the second planar region 7213, of the second portion 112 of the flexible display panel 11 to be bent into a curved shape along a direction going away from the first fixture 71. The curvature of a partial region of the first portion 111 is different from the curvature of the region, bent into the curved shape, of the second portion 112. The partial region of the first portion 111 is opposite to the region, bent into the curved shape, of the second portion 112.

For example, in the embodiments illustrated in FIG. 18, the partial region of the region of the first portion 111 is flat plate-shaped. In other embodiments, in the folded state, the partial region of the first portion 111 is bent into a curved shape along a direction going away from the second fixture 72, and the curvature of the region, bent into the curved shape, of the first portion 111 is greater than the curvature of the region, bent into the curved shape, of the second portion 112. That is, the flexible display panel is bent into the shape illustrated in FIG. 3.

A bending test of the flexible display panel 11 is performed by the first fixture 71 and the second fixture 72 to test the magnitude of the stress on the flexible display panel 11 when bent into an asymmetrical teardrop shape, which aids in the design and fabrication of the display device illustrated in FIG. 16.

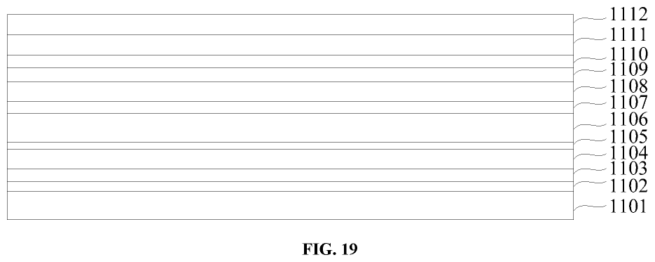

FIG. 19 is a schematic structural diagram of a flexible display panel according to some embodiments of the present disclosure. As illustrated in FIG. 19, the flexible display panel 11 includes a backside support layer 1101 and a buffer layer 1102, a back film 1103, a pressure-sensitive adhesive layer 1104, a back panel 1105, a light-emitting unit layer 1106, a first package layer 1107, a second package layer 1108, a pressure-sensitive adhesive layer 1109, a polarizer 1110, an optical adhesive layer 1111, and a cover plate 1112 that are successively stacked on the backside support layer 1101.

By performing the stress test using the bending test fixture illustrated in FIG. 18, under the same bending radius, the stress on each layer of the flexible display panel 11 bent into an asymmetric teardrop shape is smaller compared with being bent into a symmetric teardrop shape.

The technical solutions according to the embodiments of the present disclosure achieve at least the following beneficial effects.

By providing the foldable rotation shaft with the base, and the first support mechanism and the second support mechanism that are unfoldable and foldable relative to each other, in the unfolded state, the base, the first support mechanism, and the second support mechanism respectively support the bending portion, the first portion, and the second portion of the flexible display panel, such that the flexible display panel remains in the unfolded state; and in the folded state, the second support mechanism causes the region, proximal to the base, of the second portion of the flexible display panel to be bent into the curved shape along the direction going away from the first support mechanism, and the first support mechanism causes the curvature of the partial region of the first part of the flexible display panel to be different from the curvature of the region, bent into the curved shape, of the second portion. Because the curvature of these two opposite regions of the first portion and the second portion are different, the flexible display panel is bent into an asymmetric teardrop shape. In this way, internal spaces of the display device corresponding to the first portion and the second portion have different shapes, which facilitates an arrangement of internal structures of the display device, and thus the internal structures of the display device are more compact.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A foldable rotation shaft, comprising: a base, a first support mechanism, and a second support mechanism; wherein
the first support mechanism and the second support mechanism are rotatably connected to the base and are unfoldable and foldable relative to each other;
in an unfolded state, the base is configured to support a bending portion of a flexible display panel, the first support mechanism is configured to support a first portion, on one side of the bending portion, of the flexible display panel, and the second support mechanism is configured to support a second portion, on the other side of the bending portion, of the flexible display panel;
the second support mechanism is configured to cause, in a folded state, a region, proximal to the base, of the second portion to be bent into a curved shape along a direction going away from the first support mechanism; and
the first support mechanism is configured to cause, in the folded state, a curvature of a partial region of the first portion to be different from a curvature of the region, bent into the curved shape, of the second portion, wherein the partial region is opposite to the region, bent into the curved shape, of the second portion.

2. The foldable rotation shaft according to claim 1, wherein in the folded state, the partial region is flat plate-shaped.

3. The foldable rotation shaft according to claim 2, wherein the first support mechanism comprises a first support plate and a connection arm, one end of the connection arm being connected to a side of the first support plate and the other end of the connection arm being rotatably connected to the base.

4. The foldable rotation shaft according to claim 2, wherein the first support mechanism comprises a first support plate- and a first rotation assembly, wherein the first rotation assembly is disposed on a surface, distal from a support surface, of the first support plate, is connected to the first support plate, and is movably connected to the base, and the first rotation assembly is configured to drive the first support plate to rotate relative to the base and move relative to the base along a direction approaching or going away from the base.

5. The foldable rotation shaft according to claim 4, wherein the first rotation assembly comprises a first swing arm, a second swing arm, and a first middle frame connector; wherein
one end of the first swing arm is rotatably connected to the base, the other end of the first swing arm is slidably connected to the first middle frame connector, and the first middle frame connector is movable relative to the first swing arm along the direction approaching or going away from the base;
one end of the second swing arm is rotatably connected to the base, and the other end of the second swing arm is rotatably connected to the first middle frame connector; and
the first support plate is fixedly connected to the first middle frame connector.

6. The foldable rotation shaft according to claim 3, wherein the second support mechanism comprises a second support plate and a second rotation assembly, the second rotation assembly being disposed on a surface, distal from a support surface, of the second support plate and being movably connected to the second support plate;
wherein the second rotation assembly is movably connected to the base and is configured to drive the second support plate to move relative to the base, and in the folded state, an included angle between the support surface of the second support plate and the support surface of the first support plate is an acute angle, an opening of the included angle facing toward the base.

7. The foldable rotation shaft according to claim 6, wherein the second rotation assembly comprises a third swing arm, a fourth swing arm, and a second middle frame connector; wherein
one end of the third swing arm is rotatably connected to the base, the other end of the third swing arm is slidably connected to the second middle frame connector, and the second middle frame connector is movable relative to the third swing arm along the direction approaching or going away from the base;
one end of the fourth swing arm is rotatably connected to the base, and end of the fourth swing arm is rotatably connected to the second middle frame connector; and
the second support plate is rotatably connected to the second middle frame connector and is rotatably connected to the third swing arm.

8. The foldable rotation shaft according to claim 7, wherein
the second support plate comprises a plate body, a first connection portion, and a second connection portion, wherein the first connection portion and the second connection portion are disposed on a same surface of the plate body, are successively arranged along a direction approaching the base, and are disposed on a same side of the third swing arm and the second middle frame connector, wherein the first connection portion is rotatably connected to the second middle frame connector, and the second connection portion comprises a drive groove; and
the third swing arm comprises a first body portion and a connection rod, wherein two ends of the first body portion are respectively connected to the base and the second middle frame connector, and the connection rod is disposed between the base and the second middle frame connector, is disposed on a side, proximal to the second connection portion, of the first body portion, is partially within the drive groove, and is slidably connected to the second connection portion.

9. The foldable rotation shaft according to claim 8, wherein
a slot is disposed on a side, proximal to the base, of the second middle frame connector, wherein guiding chutes are disposed on two opposite side walls of the slot; and
guiding protrusions are disposed on two opposite sides of the first body portion, wherein the guiding protrusions are disposed on an end, distal from the base, of the first body portion, the end, distal from the base, of the first body portion is within the slot, and the guiding protrusions.

10. The foldable rotation shaft according to claim 1, wherein
the second support mechanism is configured to cause, in the folded state, the region, proximal to the base, of the second portion to be bent into the curved shape along the direction going away from the first support mechanism; and
the first support mechanism is configured to cause, in the folded state, the partial region to be bent into a curved shape along a direction going away from the second support mechanism, and a curvature of the region, bent into the curved shape, of the first portion is greater than the curvature of the region, bent into the curved shape, of the second portion.

11. The foldable rotation shaft according to claim 10, wherein
the first support mechanism comprises a first support plate and a first rotation assembly, wherein the first rotation assembly is disposed on a surface, distal from a support surface, of the first support plate, is movably connected to the first support plate, and is movably connected to the base, and the first rotation assembly is configured to drive the first support plate to rotate relative to the base and move relative to the base along a direction approaching or going away from the base;
the second support mechanism comprises a second support plate and a second rotation assembly, wherein the second rotation assembly is disposed on a surface, distal from the support surface, of the second support plate, is movably connected to the second support plate, and is movably connected to the base, and the second rotation assembly is configured to drive the second support plate to rotate relative to the base and move relative to the base along the direction approaching or going away from the base; and
in the folded state, an included angle between the support surface of the second support plate and the support surface of the first support plate is an acute angle, wherein an opening of the included angle faces toward the base, and a distance between the support surface of the second support plate and an edge of the base to the base is greater than a distance between the support surface of the first support plate and the edge of the base to the base.

12. A display device, comprising: a first middle frame, a second middle frame, a flexible display panel, and a foldable rotation shaft; wherein
the foldable rotation shaft comprises: a base, a first support mechanism, and a second support mechanism; wherein
the first support mechanism and the second support mechanism are rotatably connected to the base and are unfoldable and foldable relative to each other;
in an unfolded state, the base is configured to support a bending portion of a flexible display panel, the first support mechanism is configured to support a first portion, on one side of the bending portion, of the flexible display panel, and the second support mechanism is configured to support a second portion, on the other side of the bending portion, of the flexible display panel;
the second support mechanism is configured to cause, in a folded state, a region, proximal to the base, of the second portion to be bent into a curved shape along a direction going away from the first support mechanism; and
the first support mechanism is configured to cause, in the folded state, a curvature of a partial region of the first portion to be different from a curvature of the region, bent into the curved shape, of the second portion, wherein the partial region is opposite to the region, bent into the curved shape, of the second portion; and
the first middle frame is connected to the first support mechanism of the foldable rotation shaft, the second middle frame is connected to the second support mechanism of the foldable rotation shaft, and the flexible display panel comprises the bending portion, and the first portion and the second portion that are disposed on two opposite sides of the bending portion, wherein the first portion is connected to the first middle frame, and the second portion is connected to the second middle frame.

13. The display device according to claim 12, wherein a thickness of the first middle frame is less than a thickness of the second middle frame.

14. A bending test fixture of a flexible display panel, comprising: a first fixture and a second fixture that are unfoldable and foldable relative to each other; wherein
the first fixture comprises a first support surface that is planar; and
the second fixture comprises a second support surface, wherein the second support surface comprises a first planar region, an inclined region, and a second planar region, wherein the first planar region and the second planar region are not coplanar, and the inclined region is disposed between the first planar region and the second planar region and is connected to the first planar region and the second planar region;
wherein the first support surface and the second support surface are configured to be respectively connected to a first portion and a second portion that are disposed on two sides of a bending portion of a flexible display panel, and the second planar region is proximal to the bending portion; and
the bending test fixture is configured to cause, in a folded state, a region, within the inclined region and the second planar region, of the second portion to be bent into a curved shape toward a direction going away from the first fixture, wherein a curvature of a partial region of the first portion is different from a curvature of the region, bent into the curved shape, of the second portion, and the partial region is opposite to the region, bent into the curved shape, of the second portion.

15. The bending test fixture according to claim 14, wherein
in the folded state, the partial region is flat plate-shaped; or
in the folded state, the partial region is bent into a curved shape along a direction going away from the second fixture, and a curvature of the region, bent into the curved shape, of the first portion is greater than the curvature of the region, bent into the curved shape, of the second portion.

16. The display device according to claim 12, wherein in the folded state, the partial region is flat plate-shaped.

17. The display device according to claim 16, wherein the first support mechanism comprises a first support plate and a connection arm, one end of the connection arm being connected to a side of the first support plate and the other end of the connection arm being rotatably connected to the base.

18. The display device according to claim 16, wherein the first support mechanism comprises a first support plate and a first rotation assembly, wherein the first rotation assembly is disposed on a surface, distal from a support surface, of the first support plate, is connected to the first support plate, and is movably connected to the base, and the first rotation assembly is configured to drive the first support plate to rotate relative to the base and move relative to the base along a direction approaching or going away from the base.

19. The display device according to claim 18 wherein the first rotation assembly comprises a first swing arm, a second swing arm, and a first middle frame connector; wherein
one end of the first swing arm is rotatably connected to the base, the other end of the first swing arm is slidably connected to the first middle frame connector, and the first middle frame connector is movable relative to the first swing arm along the direction approaching or going away from the base;
one end of the second swing arm is rotatably connected to the base, and the other end of the second swing arm is rotatably connected to the first middle frame connector; and
the first support plate is fixedly connected to the first middle frame connector.

20. The display device according to claim 17, wherein the second support mechanism comprises a second support plate and a second rotation assembly, the second rotation assembly being disposed on a surface, distal from a support surface, of the second support plate and being movably connected to the second support plate;
wherein the second rotation assembly is movably connected to the base and is configured to drive the second support plate to move relative to the base, and in the folded state, an included angle between the support surface of the second support plate and the support surface of the first support plate is an acute angle, an opening of the included angle facing toward the base.
